(19) United States
(12) Patent Application Publication
(10) Pub. No.: US 2005/0134373 A1
(43) Pub. Date: Jun. 23, 2005

(54) Switchable gain amplifier

(76) Inventors: Po-Yu Chen, Taipei City (TW); Shu-Fen Wei, Hsinchu City (TW)

Correspondence Address: RABIN & BERDO, P.C., Suite 500, 1101 14th Street, N.W., Washington, DC, 20005, US

(21) Appl. No.: 11/013,739

(22) Filed: Dec. 17, 2004

(30) Foreign Application Priority Data
Dec. 18, 2003 (TW) 92136050

(51) Int. Cl. H03F 1/14

(52) U.S. Cl. 330/51

(57) ABSTRACT

A switchable gain amplifier is provided. The first amplifier unit includes a first input terminal to receive input signals, a control terminal, and a first output terminal to output a first output signal corresponding to the first gain mode. The second amplifier unit includes a second input terminal, and a second output terminal to output a second output signal corresponding to the second gain mode. The switch unit is serially connected between the first and second input terminals. When the switch unit is turned off and the control signal is in the first level, the gain amplifier is set in the first gain mode, whereas when the switch unit is turned on and the control signal is in the second level, the gain amplifier is set in the second gain mode.

This application claims the benefit of Taiwan application Serial No. 92136050, filed Dec. 18, 2003, the subject matter of which is incorporated herein by reference.

### BACKGROUND OF THE INVENTION

1. Field of the Invention

The invention relates in general to a switchable gain amplifier, and more particularly to a switchable gain amplifier, which can be switched between a high gain mode and a low gain mode to avoid the distortion of output signals.

2. Description of the Related Art

In a conventional mobile phone, the signal received by the antenna will be inputted into a front-end low noise amplifier (LNA) of a radio frequency receiver to be amplified so as to suppress noise and improve receiving sensitivity. To achieve the desired level of high sensitivity, the low noise amplifier must provide a high voltage gain for the weak signal received and maintain system linearity to avoid the distortion of the output signal. However, when the system is operated at a high gain mode, the operation of the LNA might be outside the linear region and reduce mobile phone sensitivity if the power of the input signal is too large.

It is therefore necessary to switch a mobile phone to different gain mode according to the power of the input signal if both high sensitivity and good linearity are desired by a mobile phone. A gain amplifier having a high gain mode and a bypass mode is disclosed in PCT patent whose patent number is WO0215397. Referring to FIG. 1, a circuit structure of the gain amplifier mentioned above is shown. Gain amplifier 100 mainly includes a bipolar junction transistor (BJT) T1, a bypass network 110 and a biasing circuit 120. The bypass network 110 connects the base B and collector C of the transistor T1 to provide the gain amplifier 100 with a bypass mode. The biasing circuit 120, accompanied by the operation of the transistor T1, connects the base B of the transistor T1 and provides the gain amplifier 100 with a high gain mode. Of which, an inductance L_{E} is serially connected to an emitter E for regulating the gain value of the transistor T1. The bypass network 110 includes a capacitor C3 and a switch S2. The biasing circuit 120 includes a current source 122 and a switch S1.

When the inputted radio frequency signal RF is a weak signal, the switch S1 will be turned on while the switch S2 will be turned off, so that the current source 122 can provide the transistor T1 with a base current. Therefore, the weak signal RF can be amplified and outputted by the transistor T1 to achieve the desired gain effect and avoid distortion. When the input radio frequency signal RF is a stronger signal, the switch S1 will be turned off while the switch S2 will be turned on. Meanwhile, the transistor is turned off because the current source 122 cannot provide the transistor T1 with a base current; the switch S2 is turned on, so that the input signal RF is outputted through the bypass network 110 and that the linearity of system operation is maintained. Despite that the bypass network 110 provides a bypass mode to prevent the distortion of the input signal RF, the loss still left uncompensated and the voltage gain becomes negative. Consequently, the desired sensitivity of signal reception still cannot be achieved. When the switch S1 is used to control the conduction of the transistor T1, the switch will need a longer response time. Furthermore, when the switch S1 is turned off, a capacitance value would still remain across the base B and the emitter E of the transistor T1, leading to a poor input impedance match of the gain amplifier 100.

### SUMMARY OF THE INVENTION

It is therefore an object of the invention to provide a switchable gain amplifier, which uses two cascade amplifier units to provide the amplifier with necessary high gain mode and low gain mode. By means of the switch unit and the control signal for controlling each amplifier unit, the gain amplifier can switch between a high gain mode and a low gain mode according to the strength of the input signal. Therefore, the good linearity of system operation and impedance match of various gain modes can be maintained.

The invention achieves the above-identified object by providing a switchable gain amplifier, which can be switched between a first gain mode and a second gain mode. The gain amplifier includes a first amplifier unit, a second amplifier unit, and a switch unit. The first amplifier unit is for providing the first gain mode. The first amplifier unit includes a first input terminal, a control terminal, and a first output terminal. The first input terminal is for receiving an input signal. The control terminal is for receiving a control signal. The first output terminal is for outputting a first output signal corresponding to the first gain mode. When the control signal is in a first level, the first amplifier unit is turned on; while the control signal is in a second level, the first amplifier unit is turned off.

The second amplifier unit is for providing the second gain mode. The second amplifier unit includes a second input terminal and a second output terminal. The second output terminal, which connects the first output terminal, is for outputting a second output signal corresponding to the second gain mode. Besides, the switch unit is serially connected between the first input terminal and the second input terminal. When the switch unit is turned off and the control signal is in the first level, the gain amplifier is set to be in the first gain mode; whereas when the switch unit is turned on and the control signal is in the second level, the gain amplifier is set to be in the second gain mode. The gain amplifier further includes a first match unit, which is connected to the first input terminal for regulating the first input impedance as the gain amplifier is set in the first gain mode. The second match unit, which is connected between the transistor and the second input terminal, is for regulating the second input impedance the gain amplifier is set in the second gain mode. The first input terminal further connects a bias current source. Therefore, the second amplifier unit can be switched between the high gain mode and the low gain mode to avoid the distortion of the output signal according to the strength of the input signal.

To achieve the above identified objects of the invention, a switchable gain amplifier, which can be switched between a first gain mode and a second gain mode is provided. The gain amplifier includes a first amplifier unit, a second amplifier unit, and a switch unit. The first amplifier unit is for providing a first gain mode. The first amplifier unit includes a first transistor and a third transistor. The first transistor includes a first input terminal for receiving an input signal. The third transistor, which is cascaded with the first transistor, includes a first control terminal for receiving the first control signal. The first output terminal is for outputting a first output signal corresponding to the first gain mode. When the first control signal is in the first level, the third transistor is turned on; when the first control signal is in the second level, the third transistor is turned off.

The second amplifier unit is for providing the second gain mode. The second amplifier unit includes a second transistor and a fourth transistor. The second transistor includes a second input terminal. The fourth transistor, which is cascaded with the second transistor, includes a second control terminal for receiving a second control signal. The second output terminal connects the first output terminal for outputting a second output signal corresponding to the second gain mode. When the second control signal is in the first level, the fourth transistor is turned on; whereas when the second control signal is in the second level, the fourth transistor is turned off. The switch unit is serially connected in between the first input terminal and the second input terminal. When the switch unit is turned off, the first control signal is in the first level and the second control signal is in the second level, the gain amplifier is set in the first gain mode, whereas when the switch unit is turned on, the first control signal is in the second level and the second control signal is in the first level, the gain amplifier is set in the second gain mode. The first transistor and the second transistor have the same specifications, and so do the third transistor and the fourth transistor have the same specifications.

The first transistor includes a first base, a first emitter, and a first collector. The first base connects the first input terminal, while the first emitter connects the first inductance. The third transistor includes a third base, a third emitter, and a third collecor. The third base connects the first control terminal. The third emitter connects the first collector, while the third collector connects the first output terminal. The second transistor includes a second base, a second emitter, and a second collector. The second base connects the second input terminal, while the second emitter connects the second inductance. The fourth transistor includes a fourth base, a fourth emitter, and a fourth collector. The fourth base connects the second control terminal. The fourth emitter connects a second collector. The fourth collector connects the second output terminal. The first input terminal further connects the bias current source. By means of the first amplifier unit and the second amplifier unit which are cascaded together and the switch unit, the gain amplifier can switch between the first gain mode and the second gain mode to avoid the distortion of the output signal. Meanwhile, the system can have a broader signal bandwidth and a better isolation of input impedance and output impedance.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a circuit structure of a conventional gain amplifier; and

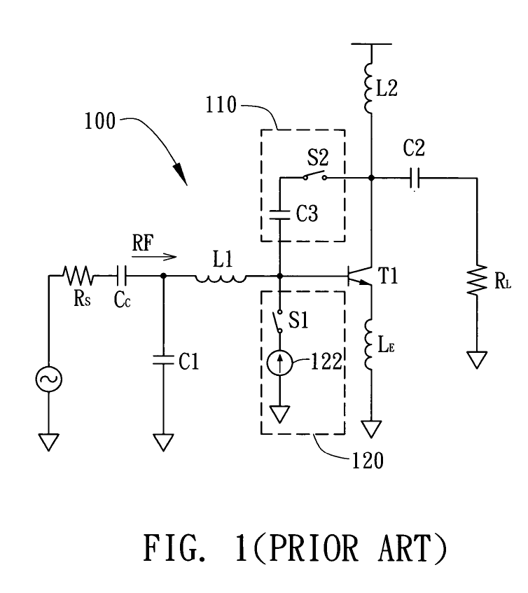

FIG. 2 is a circuit structure of a gain amplifier according to a preferred embodiment of the invention.

### DETAILED DESCRIPTION OF THE INVENTION

A key feature of the invention is using two cascade amplifier units to respectively provide a high gain mode and a low gain mode. By means of the switch unit and the control signal of respective amplifier unit, the gain amplifier can be switched between a high gain mode and a low gain mode to maintain good linearity of system operation and impedance match of various gain modes according to the strength of the input signal.

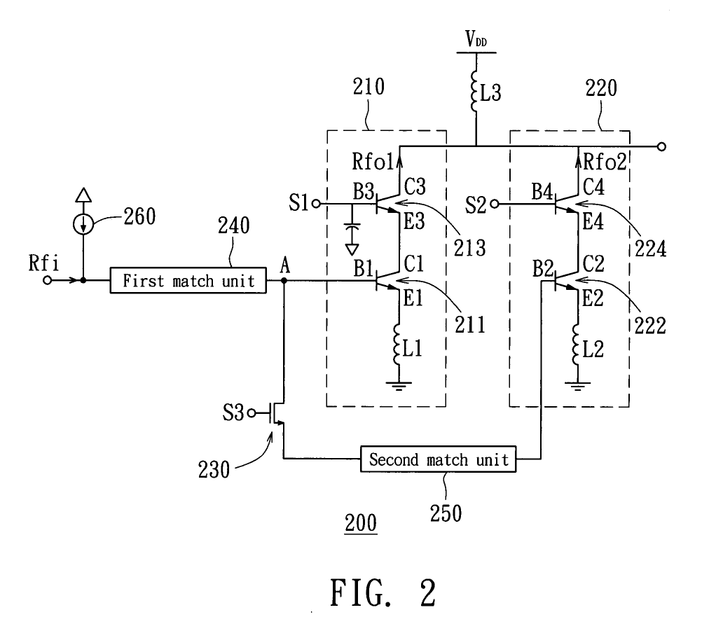

Referring to FIG. 2, a circuit structure of a gain amplifier according to a preferred embodiment of the invention is shown. The gain amplifier 200, a front-end low noise amplifier of a radio frequency receiver for instance, includes a first amplifier unit 210 and a second amplifier unit 220 for providing a high gain mode and a low gain mode respectively. The first amplifier unit 210 includes a first transistor 211 and a third transistor 213, which are cascaded together. The second amplifier unit 220 includes a second transistor 222 and a fourth transistor 224, which are cascaded together. The first transistor 211, the second transistor 222, the third transistor 213, and the fourth transistor 224 can be n-channeled bipolar junction transistors (BJT). The first transistor 211 includes a first base B1 for receiving a radio frequency input signal Rfi, a first emitter E1 for serially connecting a first inductance L1, and a first collector C1, so as to form a common-emitter amplifier. The third transistor 213 includes a third base B3 for receiving a first control signal S1, a third emitter E3 for connecting the first collector C1, and a third collector C3 for connecting the third inductance L3 to output a first output signal Rfo1 corresponding to the high gain mode. When the first control signal S1 is in a high level, the third transistor 213 is turned on, whereas when the first control signal S1 is in a low level, the third transistor 213 is turned off. The first inductance L1 disclosed above is for regulating the gain value Gain of the first amplifier unit 210 so as to provide a high gain output. For example, when L1 is 0.6 nH and L3 is 5 nH, Gain=18 dB.

Besides, the second transistor 222 includes a second base B2, a second emitter E2 for serially connecting a second inductance L2, and a second collector C2 so as to form a common-emitter amplifier. The fourth transistor 224 includes a fourth base B4 for receiving a second control signal S2, a fourth emitter E4 for connecting a second collector C2, and a fourth collector C4 for connecting a third collector C3 to output a second output signal Rfo2 corresponding to the low gain mode. The second inductance L2 is for regulating gain value Gain of the second amplifier unit 220 to provide a low gain output approximately of 0 dB to 10 dB. For example, when L2 is 1.6 nH and L3 is 5 nH, Gain=0 dB. When the second control signal S2 is in a high level, the fourth transistor 224 is turned on; whereas when the second control signal S2 is in a low level, the fourth transistor 224 is turned off. The gain amplifier 200 includes a switch unit 230 serially connected in between the first base B1and the second base B2. The switch unit 230, an N-type metal oxide semiconductor transistor (NMOS transistor) for instance, has a gate G to receive a third control signal S3. When the control signal S3 is in a high level, the switch unit 230 is turned on; whereas when the control signal S3 is in a low level, the switch unit 230 is turned off. The radio frequency signal Rfi disclosed above can also be inputted through the second transistor 222.

The gain amplifier 200 disclosed above further includes a first match unit 240 disposed in front end of the junction A between the switch unit 230 and the first base B1 for regulating the input impedance of the gain amplifier 200 when switched to the high gain mode, and a second match unit 250 connected in between the switch unit 230 and the second base G2 for regulating the input impedance of the gain amplifier 200 when switched to the low gain mode, so that the amplifier has the same input impedance regardless of being in a high gain mode or in a low gain mode. The first match unit 240 and the second match unit 250 include impedance regulating elements, such as a resistor, a capacitor and an inductance. The second match unit 250 can be a 0.5 pF to 0.8 pF capacitor. The gain amplifier 200 includes a bias current source 260 for providing the first transistor 211 and the second transistor 222 with a base current necessary for operation.

As disclosed above, when the radio frequency signal Rfi is a weak signal input, the second control signal S2 and the third the control signal S3 are both set in the low level, while the first control signal S1 is set in the high level. Meanwhile, neither the switch unit 230 not the fourth transistor is turned on, while the third transistor 213 is turned on. Therefore, the radio frequency signal Rfi can only be input to the first amplifier unit 210 but not to the second amplifier unit 220. Consequently, the gain amplifier 200 is in the high gain mode, and the enhanced output signal Rfo1 maintains the quality of the original input signal Rfi without distortion. When the radio frequency signal Rfi is a strong input signal, the second control signal S2 and the third the control signal S3 will be switched to the high level, while the first control signal S1 is switched to the low level. Meanwhile, both the switch unit 230 and the fourth transistor 224 are turned on, while the third transistor 213 is turned off. Therefore, the radio frequency signal Rfi can only be input to the second amplifier unit 220, so that the gain amplifier 200 is switched to the low gain mode. The signal Rfo2 outputted under a low gain mode has a smaller gain, however, it is sufficient to provide good reception sensitivity for a radio frequency receiver. Meanwhile, the output signal Rfo2 can still be free of distortion.

Besides, another feature of the invention is that the first amplifier unit 210 and the second amplifier unit 220 respectively uses cascaded transistors 211, 213 and cascaded transistors 222, 224, so that the radio frequency receiver can have a broader signal bandwidth. Furthermore, the amplifier of such design can have a better isolation of input impedance and output impedance and have a larger voltage gain. The first transistor 211 has the same specifications with the third transistor 213, and so does the second transistor 222 have the same specification with the fourth transistor 224. When the gain amplifier 200 is switched to the high gain mode, the switch unit 230 is turned off; meanwhile, the fourth transistor 224 is set in a turn-off status. By doing so, it can be assured that the second transistor 222 and the fourth transistor 224 will not be the same with the transistor T1 of prior art, which forms a capacitor to affect the output impedance match of the gain amplifier 200 even the switch S1 is already turned off. Furthermore, the third collector C3 and the fourth collector C4 are serially connected to voltage V_{DD} through the shared third inductance L3, so that the output impedance of the gain amplifier 200 will be the same regardless of being in a high gain mode or a low gain mode.

In terms of input impedance, since the first inductance L1 and the second inductance L2 used by the first amplifier unit 210 and the second amplifier unit 220 are different and that the input signal Rfi reaches the switch unit 230 before being inputted to the second amplifier unit 220, the input impedance of the gain amplifier 200 in the high gain mode does not match with that in low gain mode. To match with the output impedance required in the front end device of the gain amplifier, the first match unit 240 disclosed above is used to regulate the input impedance value under high gain mode operation while the second match unit 250 disclosed above is used to regulate the input impedance value under low gain mode operation, so that the gain amplifier 200 can have the same input impedance regardless of being in a high gain mode or a low gain mode.

According to the preferred embodiment disclosed above, the gain amplifier of the invention has the advantages of:
1. Using two amplifier units to work with a switch unit, the gain amplifier can be switched between a high gain mode and a low gain mode according to the strength of the input signal, which not only provides the needed signal gain, but also maintains high linearity of the gain amplifier;
2. Using two cascade amplifiers to respectively provide a high gain mode and a low gain mode, the gain amplifier can have a better isolation of input impedance and output impedance and a broader signal bandwidth, furthermore, since the two cascade amplifiers are of the same specifications and the output terminal of the two cascade amplifiers share the same load inductance, the gain amplifier has the same output impedance when operating under two different gain modes;
3. Using two amplifier units to respectively provide a high gain mode and a low gain mode and using a MOS transistor as the switch unit, serially connected in between two input terminals of the amplifier units, provides an even better switching effect for the switch unit, furthermore, using a match unit to regulate the input impedance of the gain amplifier, the gain amplifier has the same input impedance when operating under different gain modes; and
4. By connecting the output terminals of the two amplifier units of the gain amplifier with a common load inductance and connecting the input terminals of the two amplifier units of the gain amplifier with the common bias current source, the area of the circuit layout can be effectively reduced.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A switchable gain amplifier, switched between a first gain mode and a second gain mode, the gain amplifier comprising:
a first amplifier unit for providing a first gain mode, the first amplifier comprising:
a first input terminal for receiving an input signal;
a control terminal for receiving a control signal; and
a first output terminal for outputting a first output signal corresponding to the first gain mode, wherein when the control signal is in a first level, the first amplifier unit is turned on, whereas when the control signal is in a second level, the first amplifier unit is turned off;
a second amplifier unit for providing a second gain mode, the second amplifier unit comprising:
a second input terminal;
a second output terminal connecting the first output terminal for outputting a second output signal corresponding to the second gain mode; and
a switch unit serially connected in between the first input terminal and the second input terminal;
wherein, when the switch unit is turned off and the control signal is in the first level, the gain amplifier is set in the first gain mode, whereas when the switch unit is turned on and the control signal is in the second level, the gain amplifier is set in the second gain mode.

2. The gain amplifier according to claim 1, wherein the first gain mode is a high gain mode, and the second gain mode is a low gain mode.

3. The gain amplifier according to claim 1, wherein the first amplifier unit comprises an n-channel bipolar junction transistor (BJT) with the base of the BJT transistor connecting the control terminal, and the first level is a high level, while the second level is a low level.

4. The gain amplifier according to claim 1, wherein the switch unit is a P-type metal oxide semiconductor transistor, and when the gate of the transistor has a high voltage level, the switch unit is turned on, whereas when the gate of the transistor has a low voltage level, the switch unit is turned off.

5. The gain amplifier according to claim 1, wherein the gain amplifier comprises a first match unit, connected to the first input terminal, for regulating a first input impedance as the gain amplifier is set in the first gain mode; and a second match unit, connected in between the switch unit and the second input terminal, for regulating a second input impedance as the gain amplifier is set in the second gain mode.

6. The gain amplifier according to claim 1, wherein the first match unit and the second match unit are an impedance regulating element.

7. The gain amplifier according to claim 1, wherein the first amplifier unit comprises a first common-emitter amplifier whose base connects the first input terminal, and the second amplifier unit comprises a second common-emitter amplifier whose base connects the second input terminal.

8. The gain amplifier according to claim 7, wherein the emitter of the first common-emitter amplifier is serially connected to a first inductance for regulating a first gain value of the first amplifier unit, whereas the emitter of the second common-emitter amplifier is serially connected to a second inductance for regulating a second gain value of the second amplifier unit.

9. The gain amplifier according to claim 8, wherein the first input terminal connects a bias current source for providing a base current necessary for the operation of the first common-emitter and the second common-emitter.

10. A switchable gain amplifier, switched between a first gain mode and a second gain mode, the gain amplifier comprising:
a first amplifier unit for providing a first gain mode, the first amplifier unit comprising:
a first transistor, comprising a first input terminal for receiving a input signal; and
a third transistor cascaded with the first transistor, the third transistor comprising a first control terminal for receiving a first control signal, and a first output terminal for outputting a first output signal corresponding to the first gain mode, wherein when the first control signal is in a first level, the third transistor is turned on, whereas when the first control signal is in a second level, the third transistor is turned off;
a second amplifier unit for providing a second gain mode, the second amplifier unit comprising:
a second transistor, comprising a second input terminal; and
a fourth transistor cascaded with the second transistor, the fourth transistor comprising a second control terminal for receiving a second control signal, and a second output terminal connecting the first output terminal for outputting a second output signal corresponding to the second gain mode, wherein when the second control signal is in a first level, the fourth transistor is turned on, whereas when the second control signal is in a second level, the fourth transistor is turned off; and
a switch unit serially connected in between the first input terminal and the second input terminal;
wherein, when the switch unit is turned off, the first control signal is in the first level, and the second control signal is in the second level, the gain amplifier is set in the first gain mode, whereas when the switch unit is turned on, the first control signal is in the second level, and the second control signal is in the first level, the gain amplifier is set in the second gain mode.

11. The gain amplifier according to claim 10, wherein the first gain mode is a high gain mode, and the second gain mode is a low gain mode.

12. The gain amplifier according to claim 10, wherein the first transistor and the second transistor are of the same specifications and so are the third transistor and the fourth transistor of the same specifications.

13. The gain amplifier according to claim 10, wherein the first transistor, the second transistor, the third transistor and the fourth transistor are bipolar junction transistors.

14. The gain amplifier according to claim 13, wherein the first transistor comprises a first base connecting the first input terminal, a first emitter connecting the first inductance, and a first collector, and the third transistor comprises a third base connecting the first control terminal, a third emitter connecting the first collector, and a third collector connecting the first output terminal.

15. The gain amplifier according to claim 14, wherein the second transistor comprises a second base connecting the second input terminal, a second emitter connecting the second inductance, and a second collector, and the fourth transistor comprises a fourth base connecting the second control terminal, a fourth emitter connecting the second collector, and a fourth collector connecting the second output terminal.

16. The gain amplifier according to claim 15, wherein the first input terminal connects a bias current source for providing the first transistor and the second transistor with base currents necessary for operation.

17. The gain amplifier according to claim 10, wherein the first level is a high level, and the second level is a low level.

18. The gain amplifier according to claim 10, wherein the switch unit is a P-type metal oxide semiconductor transistor, and when the gate of the transistor has a high voltage level, the switch unit is turned on, whereas when the gate of the transistor has a low voltage level, the switch unit is turned off.

19. The gain amplifier according to claim 10, wherein the gain amplifier further comprises a first match unit connected to the first input terminal for regulating a first input impedance as the gain amplifier is set in the first gain mode, and a second match unit connected in between the switch unit and the second input terminal for regulating a second input impedance as the gain amplifier is set in the second gain mode.

20. The gain amplifier according to claim 19, wherein the first match unit and the second match unit are regulating impedance elements.
